(19) United States
(12) Patent Application Publication
(10) Pub. No.: US 2026/0247624 A1
(43) Pub. Date: Aug. 20, 2026

(54) SEMICONDUCTOR MEMORY DEVICE HAVING AUXILIARY CONDUCTIVE LINES

(71) Applicant: SK hynix Inc., Icheon-si Gyeonggi-do (KR)

(72) Inventor: Jeong Kyu KANG, Icheon-si Gyeonggi-do (KR)

(73) Assignee: SK hynix Inc., Icheon-si Gyeonggi-do (KR)

(21) Appl. No.: 19/301,486

(22) Filed: Aug. 15, 2025

(30) Foreign Application Priority Data
Feb. 18, 2025 (KR) 10-2025-0021005

(51) Int. Cl. H10B 43/40; G11C 16/30; H10B 43/27

(52) U.S. Cl. CPC H10B 43/40; G11C 16/30; H10B 43/27

(57) ABSTRACT

A semiconductor memory device includes a wiring array structure and a peripheral circuit structure configured to supply voltages to a first conductive line, a second conductive line, and an auxiliary conductive line between the first conductive line and the second conductive line of the wiring array structure. The peripheral circuit structure is configured to apply a third voltage having a level between a first voltage applied to the first conductive line and a second voltage applied to the second conductive line to the auxiliary conductive line.

### CROSS-REFERENCE TO RELATED APPLICATION

The present application claims priority under 35 U.S.C. § 119(a) to Korean patent application number 10-2025-0021005 filed on Feb. 18, 2025, in the Korean Intellectual Property Office, the entire contents of which application is incorporated herein by reference.

### BACKGROUND

### 1. Technical Field

Various embodiments of the present disclosure generally relate to a semiconductor memory device, and more particularly, to a semiconductor memory device having an auxiliary conductive line.

### 2. Related Art

Semiconductor memory devices are applied to various electronic systems, such as small electronic devices, automobiles, medical devices, and data centers, and they are highly integrated and high-capacity according to user needs. Semiconductor memory devices receive a power supply voltage through a power line and generate internal voltages with varying voltage levels necessary to program, read, or erase data. The power supply voltage and the internal voltages may be supplied to adjacent conductive lines, and voltages supplied to the adjacent conductive lines may be different from each other. As a voltage difference between a conductive line to which the high voltage is supplied and a conductive line to which a low voltage is supplied increases, the breakdown voltage characteristic may decrease, and thus the operation reliability of a semiconductor memory device may decrease.

### SUMMARY

According to an embodiment, a semiconductor memory device may include a wiring array structure including a first conductive line, a second conductive line, and an auxiliary conductive line extending in parallel to each other, wherein the auxiliary conductive line is disposed between the first conductive line and the second conductive line. The semiconductor memory device may also include a peripheral circuit structure including a voltage generator, the peripheral circuit structure configured to supply voltages to the first conductive line, the second conductive line, and the auxiliary conductive line. When a first voltage is applied to the first conductive line and a second voltage lower than the first voltage is applied to the second conductive line, the voltage generator may apply a third voltage having a level between the first voltage and the second voltage to the auxiliary conductive line.

According to an embodiment, a semiconductor memory device may include a wiring array structure including a first conductive line, a second conductive line, and at least two auxiliary conductive lines extending in parallel to each other, wherein the at least two auxiliary conductive lines are disposed between the first conductive line and the second conductive line. The semiconductor memory device may also include a peripheral circuit structure including a voltage generator, the peripheral circuit structure configured to supply voltages to the first conductive line, the second conductive line, and the at least two auxiliary conductive lines. When a first voltage is applied to the first conductive line and a second voltage lower than the first voltage is applied to the second conductive line, the voltage generator may apply auxiliary voltages set to different levels between the first voltage and the second voltage to the at least two auxiliary conductive lines.

### BRIEF DESCRIPTION OF THE DRAWINGS

FIGS. 1A and 1B are a plan view and a cross-sectional view, respectively, illustrating a wiring array structure of a semiconductor memory device according to an embodiment of the present disclosure;

FIG. 2 is a table illustrating voltages applied to a wiring array structure according to an embodiment of the present disclosure;

FIGS. 3A and 3B are a plan view and a cross-sectional view, respectively, illustrating a wiring array structure of a semiconductor memory device according to an embodiment of the present disclosure illustrating;

FIG. 4 is a table illustrating voltages applied to a wiring array structure according to an embodiment of the present disclosure;

FIG. 5 is a block diagram illustrating an electronic system including a semiconductor memory device according to an embodiment of the present disclosure;

FIG. 6 is a block diagram illustrating a semiconductor memory device according to an embodiment of the present disclosure;

FIG. 7 is a block diagram illustrating a charge pump of a semiconductor memory device according to an embodiment of the present disclosure;

FIG. 8 is an isometric diagram illustrating a cell array structure and a peripheral circuit structure of a semiconductor memory device according to an embodiment of the present disclosure; and

FIGS. 9A and 9B are cross-sectional views illustrating a semiconductor memory device according to embodiments of the present disclosure.

### DETAILED DESCRIPTION

Specific structural or functional descriptions disclosed herein are merely illustrative for the purpose of describing embodiments according to the concept of the present disclosure. Embodiments according to the concept of the present disclosure may be implemented in various forms and should not be construed as being limited to the specific embodiments set forth herein.

Terms such as “first” and “second” are used to distinguish between various elements and do not imply size, order, priority, quantity, or importance of the elements. For example, a first element may be named as a second element in one example, and the second element may be named as a first element in another example. Terms such as “vertical,” “over,” “lower,” “upper,” and other terms implying relative spatial relationship or orientation are utilized only for the purpose of ease of description or reference to a drawing and are not otherwise limiting. It will be understood that when an element or layer is referred to as being “on,” “connected to,” or “coupled to” another element or layer, it can be directly on, connected, or coupled to the other element or layer or intervening elements or layers may be present. In contrast, when an element is referred to as being “directly on,” “directly connected to,” or “directly coupled to” another element or layer, there are no intervening elements or layers present. The cross-hatching throughout the figures illustrates corresponding or similar areas between the figures rather than indicating the materials associated with the areas.

Some embodiments of the present disclosure are directed to semiconductor memory devices capable of improved operational reliability.

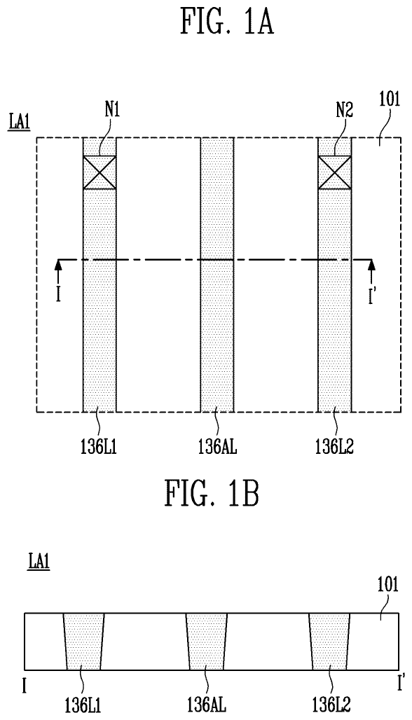

FIGS. 1A and 1B are a plan view and a cross-sectional view, respectively, illustrating a wiring array structure LA1 of a semiconductor memory device according to an embodiment of the present disclosure. FIG. 1B shows a cross-section of the wiring array structure LA1 cut along line I-I′ shown in FIG. 1A.

Referring to FIGS. 1A and 1B, the wiring array structure LA1 may include a first conductive line 136L1, a second conductive line 136L2, and an auxiliary conductive line 136AL extending in parallel to each other. The first conductive line 136L1, the second conductive line 136L2, and the auxiliary conductive line 136AL may include various conductive materials and may be disposed in a peripheral circuit insulating structure 101.

The first and second conductive lines 136L1 and 136L2 may transmit voltages required to control operation of the semiconductor memory device. In an embodiment, the first conductive line 136L1 and the second conductive line 136L2 may be connected to a first terminal N1 and a second terminal N2, respectively, which output voltages generated in the semiconductor memory device.

The auxiliary conductive line 136AL is disposed between the first conductive line 136L1 and the second conductive line 136L2. The voltages applied to the first and second conductive lines 136L1 and 136L2 may have different levels. A voltage applied to the auxiliary conductive line 136AL may be such that a voltage difference between the first conductive line 136L1 and the auxiliary conductive line 136AL and a voltage difference between the second conductive line 136L2 and the auxiliary conductive line 136AL is less than a voltage difference between first conductive line 136L1 and the second conductive line 136L2. For example, the voltage of the auxiliary conductive line 136AL may be between the voltages of the first and second conductive lines 136L1 and 136L2.

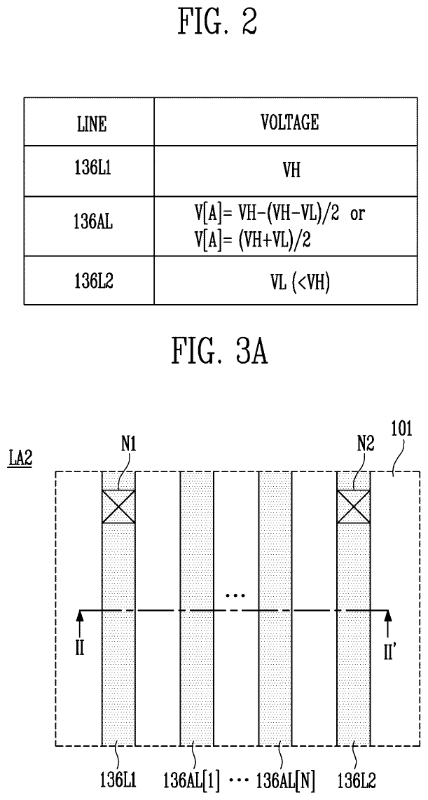

FIG. 2 is a table illustrating voltages applied to the wiring array structure LA1 according to an embodiment of the present disclosure.

Referring to FIGS. 1A and 2, when a first voltage VH is applied to the first conductive line 136L1, a second voltage VL may be applied to the second conductive line 136L2. At this time, an auxiliary voltage V[A], which is a third voltage, may be applied to the auxiliary conductive line 126AL. The first voltage VH, the second voltage VL, and the auxiliary voltage V[A] may have different levels.

In an embodiment, the second voltage VL is at a lower level than the first voltage VH, and the auxiliary voltage V[A] may be controlled at a level between the first voltage VH and the second voltage VL. Accordingly, a voltage difference between adjacent conductive lines may be controlled to be less than the voltage difference between the first voltage VH and the second voltage VL. In an embodiment, the auxiliary voltage V[A] is controlled so that the difference between the first voltage VH and the auxiliary voltage V[A] and the difference between the auxiliary voltage V[A] and the second voltage VL are the same, whereby the voltage difference between the adjacent conductive lines may be controlled evenly. At this time, the auxiliary voltage V[A] is a voltage at a level obtained by subtracting half of the difference between the first voltage VH and the second voltage VL from the first voltage VH, as illustrated in FIG. 2. For example, the auxiliary voltage V[A] is the average of the first voltage VH and the second voltage VL so that V[A]=(VH+HL)/2.

Referring to FIGS. 1A, 1B, and 2, an embodiment in which one auxiliary conductive line 136AL is disposed between the first conductive line 136L1 and the second conductive line 136L2 is described as an example in the present disclosure, but the present disclosure is not limited thereto.

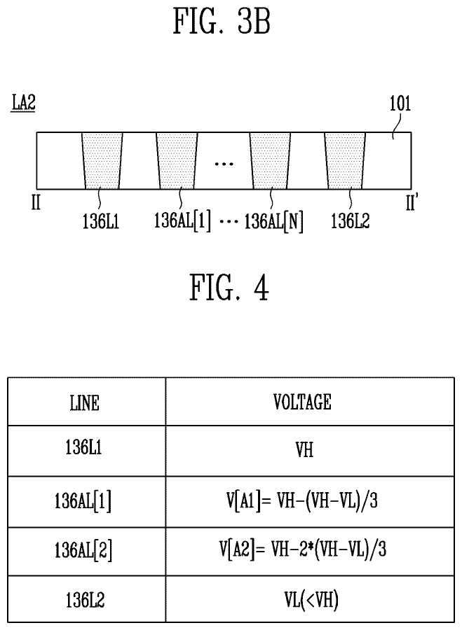

FIGS. 3A and 3B are a plan view and a cross-sectional view, respectively, illustrating a wiring array structure LA2 of a semiconductor memory device according to an embodiment of the present disclosure. FIG. 3B shows a cross-section of the wiring array structure LA2 cut along line II-II′ shown in FIG. 3A.

Referring to FIGS. 3A and 3B, the wiring array structure LA2 may include the first conductive line 136L1, the second conductive line 136L 2, and two or more auxiliary conductive lines 136AL[1] to 136AL[N] (where N is a natural number of 2 or more) extending in parallel with each other. The first conductive line 136L1, the second conductive line 136L2, and the two or more auxiliary conductive lines 136AL[1] to 136AL[N] may be spaced apart from each other by the peripheral circuit insulating structure 101.

As described with reference to FIGS. 1A and 1B, the first conductive line 136L1 and the second conductive line 136L2 may be connected to the first terminal N1 and the second terminal N2, respectively, which output voltages generated in the semiconductor memory device.

The two or more auxiliary conductive lines 136AL[1] to 136AL[N] are disposed between the first conductive line 136L1 and the second conductive line 136L2. When different voltages are applied to the first conductive line 136L1 and the second conductive line 136L 2, by applying auxiliary voltages to the two or more auxiliary conductive lines 136AL[1] to 136AL[N], a voltage difference between adjacent wirings of the wiring array structure LA2 may be reduced as compared to the voltage difference between first conductive line 136L1 and the second conductive line 136L2.

The auxiliary voltages applied to the two or more auxiliary conductive lines 136AL[1] to 136AL[N] may be controlled to levels between the voltage applied to the first conductive line 136L1 and the voltage applied to the second conductive line 136L2. In addition, to minimize or equalize the voltage difference between adjacent conductive lines of the wiring array structure LA2, the auxiliary voltages applied to the two or more auxiliary conductive lines 136AL[1] to 136AL[N] may be controlled to different levels from each other. In an embodiment, the auxiliary voltages applied to the two or more auxiliary conductive lines 136AL[1] to 136AL[N] may stepwise reduced from the voltage of the first conductive line 136L1 toward the voltage of the second conductive line 136L2. For example, the auxiliary voltages may be controlled such that the voltage difference between the adjacent conductive lines of the wiring array structure LA2 are equal.

FIG. 4 is a table illustrating voltages applied to the wiring array structure LA2 according to an embodiment of the present disclosure. FIG. 4 shows voltages applied to the wiring array structure LA2 based on an embodiment in which two auxiliary conductive lines including the first auxiliary conductive line 136AL[1] and the second auxiliary conductive line 136AL[2] are disposed between the first conductive line 136L1 and the second conductive line 136L2.

Referring to FIG. 4, when the first voltage VH is applied to the first conductive line 136L1, the second voltage VL lower than the first voltage VH may be applied to the second conductive line 136L2. At this time, a first auxiliary voltage V[A1] applied to the first auxiliary conductive line 136AL[1] and a second auxiliary voltage V[A2] applied to the second auxiliary conductive line 136AL[2] may be controlled to levels between the first voltage VH and the second voltage VL. As a result, the voltage difference between the adjacent conductive lines of the wiring array structure may be less than the difference between the first voltage VH and the second voltage VL, and the breakdown voltage characteristic of the wiring array structure may be improved. The first auxiliary voltage V[A1] and the second auxiliary voltage V[A2] are controlled so that the difference between the first voltage VH and the first auxiliary voltage V[A1], the difference between the second auxiliary voltages V[A2] and the first auxiliary voltages V[A1], and the difference between the second auxiliary voltages V[A2] and the second voltage VL are the same, whereby the voltage difference between the adjacent wirings of the wiring array structure may be minimized or equalized. In an embodiment, as illustrated in FIG. 4, the first auxiliary voltage V[A1] may be controlled to a voltage of a level obtained by subtracting a third of the difference between the first voltage VH and the second voltage VL from the first voltage VH, and the second auxiliary voltage V[A2] may be controlled at a voltage of a level obtained by subtracting two thirds of the difference between the first voltage VH and the second voltage VL from the first voltage VH.

The wiring array structures and the method of applying the voltages for the wiring array structure described with reference to FIGS. 1A, 1B, 2, 3A, 3B, and 4 may be applied to a semiconductor memory device and an electronic system including the same.

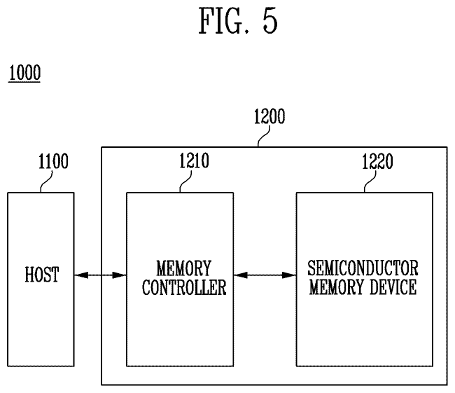

FIG. 5 is a block diagram illustrating an electronic system 1000 including a semiconductor memory device 1220 according to an embodiment of the present disclosure.

Referring to FIG. 5, the electronic system 1000 may be a computing system, a medical device, a communication device, a wearable device, a memory system, or the like. The electronic system 1000 may include a host 1100 and a storage device 1200.

The host 1100 may store data in the storage device 1200 or read data stored in the storage device 1200 based on an interface. The interface may include one or more of a Double Data Rate (DDR) interface, a Universal Serial Bus (USB) interface, a Multi-Media Card (MMC) interface, an embedded MMC (eMMC) interface, a Peripheral Component Interconnection (PCI) interface, a PCI-express (PCI-E) interface, an Advanced Technology Attachment (ATA) interface, a Serial-ATA interface, a Parallel-ATA interface, a Small Computer System Interface (SCSI), an Enhanced Small Disk Interface (ESDI), an Integrated Drive Electronics (IDE) interface, a Firewire interface, a Universal Flash Storage (UFS) interface, and a Non-Volatile Memory express (NVMe) interface.

The storage device 1200 may include a memory controller 1210 and the semiconductor memory device 1220. In an embodiment, the storage device 1200 may be a storage medium, such as a Solid-State Drive (SSD), a Universal Serial Bus (USB) memory, or the like.

The memory controller 1210 may store data in the semiconductor memory device 1220 under the control of the host 1100 or read data stored in the semiconductor memory device 1220.

The semiconductor memory device 1220 may include one memory chip or a plurality of memory chips. The semiconductor memory device 1220 may store data or output stored data under the control of the memory controller 1210.

The semiconductor memory device 1220 may be a non-volatile memory device. The semiconductor memory device 1220 may include a cell array structure and a peripheral circuit structure which controls operation of the cell array structure. The cell array structure may include a plurality of memory cells. Each memory cell may be a non-volatile memory cell. In an embodiment, each memory cell may be configured as a NAND flash memory cell, a ferroelectric memory cell, a variable resistance memory cell, or the like.

The peripheral circuit structure may be configured to control the operation of the cell array structure, and it may be connected to the wiring array structure LA1 shown in FIGS. 1A and 1B or the wiring array structure LAB2 shown in FIGS. 3A and 3B. The peripheral circuit structure may be configured to control the method of applying the voltages for the wiring array structure described with reference to FIG. 2 or FIG. 4.

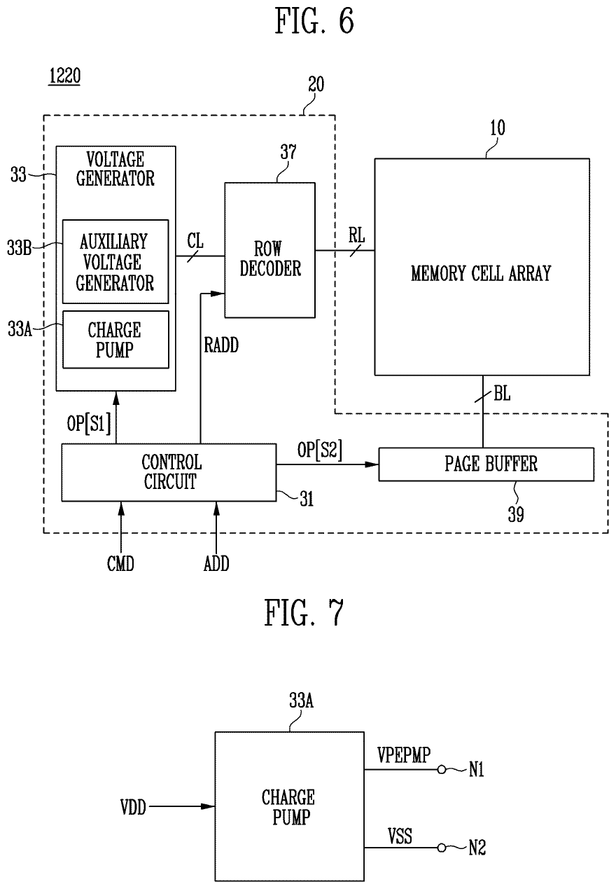

FIG. 6 is a block diagram illustrating the semiconductor memory device 1220 according to an embodiment of the present disclosure.

Referring to FIG. 6, the semiconductor memory device 1220 may include a memory cell array 10 and a peripheral circuit 20.

The memory cell array 10 may be variously configured, such as a NAND flash memory cell array, a ferroelectric memory cell array, or a variable resistance memory cell array. Hereinafter, the present disclosure will be described based on an embodiment in which the memory cell array 10 is configured as a NAND flash memory cell array, but embodiments of the present disclosure are not limited thereto.

The peripheral circuit 20 may be configured to perform a program operation to store data in memory cell array 10, a read operation to output data stored in memory cell array 10, and an erase operation to erase data stored in memory cell array 10. In an embodiment, the peripheral circuit 20 may include a control circuit 31, a voltage generator 33, a row decoder 37, and a page buffer 39.

The control circuit 31 may output operating signals OP[S1] and OP[S2], a row address RADD, and the like in response to a command CMD and an address ADD. The command CMD and the address ADD may be transmitted from an external device (for example, a memory controller) to the control circuit 31 via an input/output circuit (not shown).

The voltage generator 33 may generate and output various operating voltages used for program operations, read operations, or erase operations in response to the operating signal OP[S1]. The voltage generator 33 may include a charge pump 33A and an auxiliary voltage generator 33B. The charge pump 33A may output the above-described operating voltages to conductive lines CL in response to the operating signals OP[S1], and it may output internal voltages required for operation in the voltage generator 33 under the control of the control circuit 31. The auxiliary voltage generator 33B may output a voltage applied to the auxiliary line under the control of the control circuit 31.

The row decoder 37 may transfer the operating voltages from the conductive lines CL to local lines RL connected to memory cell array 10 in response to the row address RADD. The local lines RL may include a source select line, a drain select line, and a plurality of word lines.

The page buffer 39 may store read data received via a bit line BL in response to the operating signal OP[S2]. The page buffer 39 may sense the voltage or current of the bit line BL during the read operation. The page buffer 39 may be connected to the memory cell array 10 via the bit line BL.

The auxiliary voltage applied to the auxiliary conductive line 136AL of the wiring array structure LA1 shown in FIGS. 1A and 1B or the auxiliary voltages applied the auxiliary conductive lines 136AL[1] to 136AL[N] of the wiring array structure LA2 shown in FIGS. 3A and 3B may be controlled by the auxiliary voltage generator 33B of the voltage generator 33. The auxiliary voltage generator 33B may generate the one or more auxiliary voltages in the manner described with reference to FIG. 2 or 4 under the control of the control circuit 31.

The first and second conductive lines 136L1 and 136L2 of the wiring array structure LA1 shown in FIGS. 1A and 1B or the first and second conductive line 136L1 and 136L2 of the wiring array structure LA2 shown in FIGS. 3A and 3B may transmit some of the voltages output from the charge pump 33A.

FIG. 7 is a block diagram illustrating the charge pump 33A of the semiconductor memory device 1220 according to an embodiment of the present disclosure.

Referring to FIG. 7, the charge pump 33A may perform a pumping operation using a power supply voltage VDD. The pumping operation of the charge pump 33A may generate various levels of internal power and the operating voltages used for the operation of the semiconductor memory device 1220. In an embodiment, the charge pump 33A may output a pump generating voltage VPEPMP and a ground voltage VSS to the first terminal N1 and the second terminal N2, respectively, using the power supply voltage VDD.

The pump generating voltage VPEPMP is greater than the power supply voltage VDD and may be a high voltage between 10 V and 30 V. The pump generating voltage VPEPMP may be used to generate the operating voltages used to operate the memory cell array 10 shown in FIG. 6, or it may be used for data input/output operation.

The first conductive line 136L1 of the wiring array structure LA1 shown in FIGS. 1A and 1B or the first conductive line 136L1 of the wiring array structure LA2 shown in FIGS. 3A and 3B may be connected to the first terminal N1 to transmit the pump generating voltage VPEPMP. The second conductive line 136L2 of the wiring array structure LA1 shown in FIGS. 1A and 1B or the second conductive line 136L2 of the wiring array structure LA2 shown in FIGS. 3A and 3B may be connected to the second terminal N2 to transmit the ground voltage VSS.

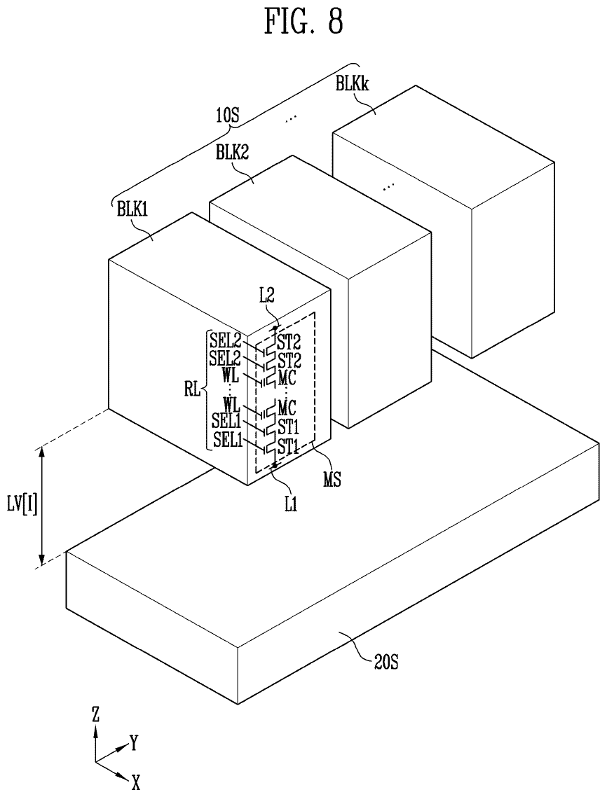

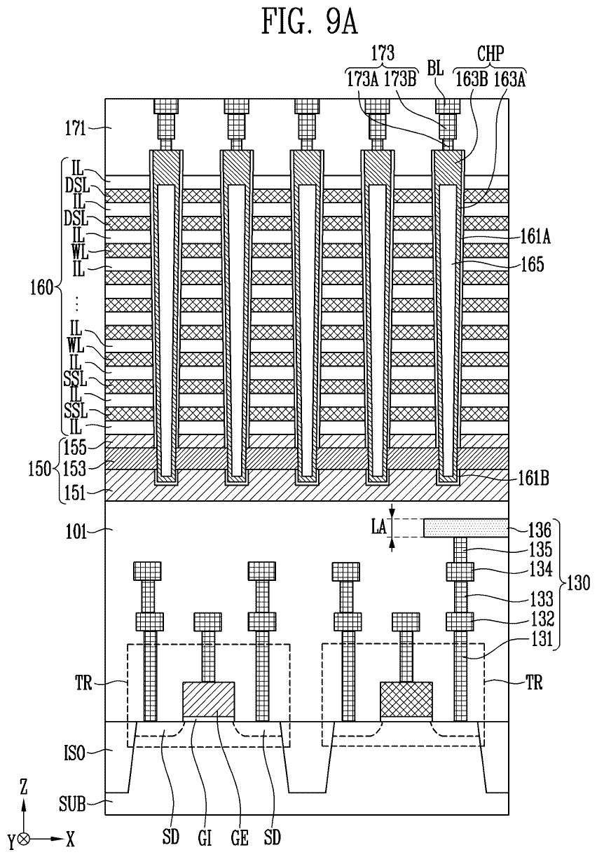

FIG. 8 is an isometric diagram illustrating a cell array structure 10S and the peripheral circuit structure of a semiconductor memory device according to an embodiment of the present disclosure.

Referring to FIG. 8, the cell array structure 10S may include a plurality of memory blocks BLK1 to BLKk (where k is a natural number greater than or equal to 2) forming the memory cell array 10 illustrated in FIG. 6. A plurality of memory cells MC of each of the plurality of memory blocks BLK1 to BLKk are arranged in three dimensions, whereby the degree of integration of memory cells within a limited area may be improved.

In an embodiment, each memory cell MC may be a NAND flash memory cell. In a NAND flash memory device, the plurality of memory cells MC may be included in a plurality of memory cell strings MS. The plurality of memory cell strings MS may be arranged in a plurality of rows and a plurality of columns in an XY plane. Each of the plurality of rows includes the memory cell strings MS arranged in the row in a first direction (for example, X-axis direction), and each of the plurality of columns includes the memory cell strings MS arranged in the row in a second direction (for example, Y-axis direction).

Each of the memory cell strings MS may be connected to a first conductive layer L1, a second conductive layer L2, and the local lines RL. One of the first conductive layer L1 and the second conductive layer L2 forms a source layer, and the other forms a bit line. The first conductive layer L1 and the second conductive layer L2 may be spaced apart from each other in a vertical direction (for example, a Z-axis direction) crossing the XY plane, and may be electrically connected to both ends of the memory cell string MS.

The local lines RL are disposed between the first conductive layer L1 and the second conductive layer L2. The local lines RL include at least one first select line SEL1, a plurality of word lines WL, and at least one second select line SEL2 spaced apart from each other in the vertical direction. One of the first select line SEL1 and the second select line SEL2 serves as the source select line, and the other serves as the drain select line. The at least one first select line SEL1 is disposed between the first conductive layer L1 and the plurality of word lines WL. In an embodiment, two first select lines SEL1 may be disposed between the first conductive layer L1 and the plurality of word lines WL. The at least one second select line SEL2 is disposed between the second conductive layer L2 and the plurality of word lines WL. In an embodiment, two second select lines SEL2 may be disposed between the second conductive layer L2 and the plurality of word lines WL. The memory cell string MS includes a first select transistor ST1, the plurality of memory cells MC, and a second select transistor ST2. One of the first select transistor ST1 and the second select transistor ST2 serves as a source select transistor, and the other serves as a drain select transistor. The first select line SEL1 is connected to a gate of the first select transistor ST1, the plurality of word lines WL are respectively connected to a plurality of gates of the plurality of memory cells MC, and the second select line SEL2 is connected to a gate of the second select transistor ST2. The first select transistor ST1, the plurality of memory cells MC, and the second select transistor ST2 may be connected in series through a channel pillar. The channel pillar includes a semiconductor material electrically connected to the first conductive layer L1 and the second conductive layer L2.

A peripheral circuit structure 20S includes transistors, resistors, and the like forming the peripheral circuit 20 illustrated in FIG. 6. Some regions of the peripheral circuit structure 20S may overlap with the cell array structure 10S in the vertical direction. Accordingly, the arrangement efficiency of the cell array structure 10S and the peripheral circuit structure 20S within a limited area may be improved.

The wiring array structure LA1 shown in FIGS. 1A and 1B or the wiring array structure LA2 shown in FIGS. 3A and 3B may be disposed at an interlayer level LV[I] between the peripheral circuit structure 20S and the cell array structure 10S. Interconnections electrically connecting the peripheral circuit structure 20S and the cell array structure 10S may be further disposed at the interlayer level LV[I].

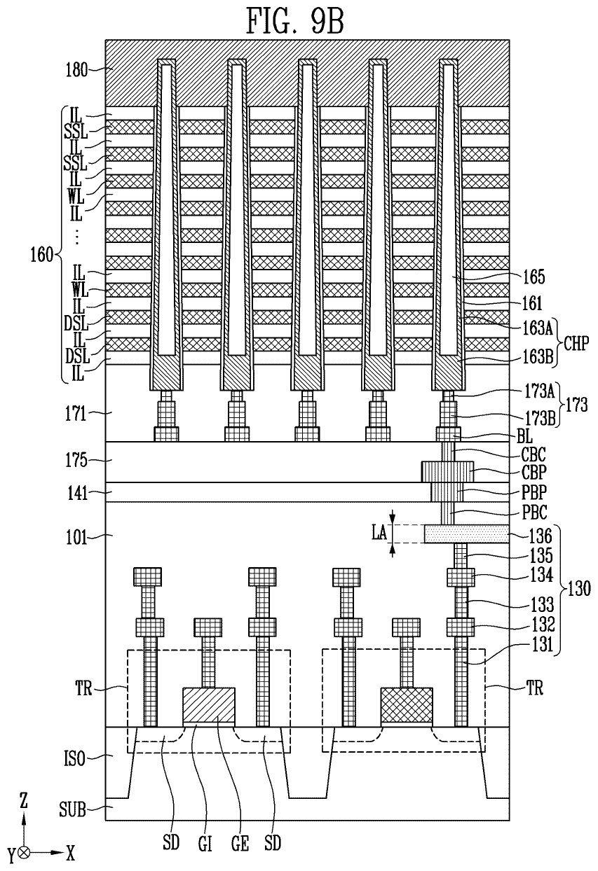

FIGS. 9A and 9B are cross-sectional views illustrating a semiconductor memory device according to embodiments of the present disclosure.

Referring to FIGS. 9A and 9B, the peripheral circuit structure of a semiconductor memory device may include a semiconductor substrate SUB in which an isolation layer ISO is formed, transistors TR, the peripheral circuit insulating structure 101, and interconnections 130.

The semiconductor substrate SUB includes a semiconductor material. In an embodiment, the semiconductor material may include one or more of a group IV semiconductor, a group III-V compound semiconductor, and a group II-VI compound semiconductor. The group IV semiconductor may include single crystal silicon (Si), polycrystalline silicon, germanium (Ge), or silicon germanium (SiGe). The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The semiconductor substrate SUB may further include a dielectric layer. In an embodiment, the semiconductor substrate SUB may be a Silicon-On-Insulator (SOI) substrate or a Germanium-On-Insulator (GeOI) substrate. The semiconductor substrate SUB may further include an organic material. In an embodiment, the semiconductor substrate SUB may include graphene.

The semiconductor substrate SUB may be a bulk wafer or an epitaxial layer grown in a Selective Epitaxial Growth (SEG) manner. Alternatively, the semiconductor substrate SUB may be a layer formed by a Metal Induced Lateral Crystallization (MILC) method, and it may partially include a metal.

The semiconductor substrate SUB may be in a single crystal, polycrystalline, or amorphous state. The semiconductor substrate SUB may include impurities of Group II, III, IV, V or VI elements. In an embodiment, the semiconductor substrate SUB may include an n-well region doped with n-type impurities, a p-well region doped with p-type impurities, or include an n-well region and a p-well region.

The semiconductor substrate SUB includes an active region partitioned by the isolation layer ISO. Each of the transistors TR includes a channel region, impurity injection regions SD, a gate insulating layer GI, and a gate electrode GE. The channel region and the impurity injection regions SD are disposed in the active region. The channel region is disposed between the impurity injection regions SD. Each of the impurity injection regions SD spaced apart from each other with the channel region therebetween may include conductive impurities to serve as a source region or a drain region of the transistor TR corresponding thereto. A majority carrier of the impurity injection regions SD may include n-type impurities or p-type impurities depending on the electrical characteristics of the transistor. In an embodiment, the impurity injection regions SD of a P-channel Metal Oxide Semiconductor (PMOS) transistor include p-type impurities as a majority carrier. In another embodiment, the impurity injection regions SD of an N-channel Metal Oxide Semiconductor (NMOS) transistor include n-type impurities as a majority carrier. The gate insulating layer GI and the gate electrode GE are stacked over the channel region.

The plurality of transistors TR and the semiconductor substrate SUB are covered with the peripheral circuit insulating structure 101. The peripheral circuit insulating structure 101 may include multiple layers of insulating layers.

The interconnections 130 may include conductive patterns 131, 132, 133, 134, 135, and 136 disposed in the peripheral circuit insulating structure 101. The conductive patterns 131, 132, 133, 134, 135, and 136 may be electrically connected to the gate electrode GE, the impurity regions SD, a via pattern, various signal transmission wirings, and the like.

Some conductive patterns of the interconnections 130 may be included in a wiring array structure LA. In an embodiment, the uppermost conductive pattern 136 of each of the interconnections 130 may be included in the wiring array structure LA. The wiring array structure LA may correspond to the wiring array structure LA1 shown in FIGS. 1A and 1B, or it may correspond to the wiring array structure LA2 shown in FIGS. 3A and 3B.

The cell array structure of the semiconductor memory device may include a doped semiconductor structure 150 or 180, a gate stack structure 160, the bit line BL, a channel pillar CHP, and a memory layer 161A or 161. The gate stack structure 160 is disposed between the doped semiconductor structure 150 or 180 and the bit line BL, and the channel pillar CHP penetrates through the gate stack structure 160 and is connected to the doped semiconductor structure 150 or 180. Some or all of the doped semiconductor structure 150 or 180 may serve as a source layer.

The gate stack structure 160 may include a plurality of conductive layers SSL, WL, and DSL and a plurality of interlayer insulating layers IL. Each of the plurality of conductive layers SSL, WL, and DSL and the plurality of interlayer insulating layers IL extends in the XY plane. The plurality of conductive layers SSL, WL, and DSL are stacked to be spaced apart from each other in the vertical direction (for example, the Z-axis direction) crossing the XY plane. The plurality of interlayer insulating layers IL are alternately stacked with the plurality of conductive layers SSL, WL, and DSL in the vertical direction.

The plurality of conductive layers SSL, WL, and DSL include at least one source select line SSL, at least one drain select line DSL, and the plurality of word lines WL disposed between the source select line SSL and the drain select line DSL. The source select line SSL is connected to a gate electrode of the source select transistor, the drain select line DSL is connected to a gate electrode of the drain select transistor, and the plurality of word lines WL are respectively connected to a plurality of gates of the plurality of memory cells MC. Each of the plurality of conductive layers SSL, WL, and DSL may include various conductive materials, such as a doped semiconductor layer and a metal layer. The doped semiconductor layer may include a doped silicon layer. The metal layer may include tungsten, copper, molybdenum, or the like. Each of the plurality of conductive layers SSL, WL, and DSL may further include a metal barrier layer. The metal barrier layer may include a metal nitride layer, and the metal nitride layer may include titanium nitride, tantalum nitride, molybdenum nitride, or the like. In an embodiment, the metal barrier layer may include a double layer of titanium and titanium nitride. Each of the plurality of interlayer insulating layers IL may include an insulating material layer, such as a silicon oxide layer or a silicon oxynitride layer.

The channel pillar CHP extends vertically to penetrate through the plurality of conductive layers SSL, WL, DSL and the plurality of interlayer insulating layers IL of a gate stack structure GS. The channel pillar CHP includes a channel layer 163A. The channel layer 163A may include a semiconductor material, such as silicon (Si), germanium (Ge), or a mixture thereof, which may be utilized as a channel region of a string of memory cells. The channel layer 163A may have a tubular shape. The channel pillar CHP, which includes the channel layer 163A having a tubular shape, may further include a core insulating layer 165 and a capping pattern 163B disposed in a tubular central region formed of the channel layer 163A. The capping pattern 163B may include a semiconductor layer doped with conductive impurities. The conductive impurities may include n-type impurities, or they may include n-type impurities and p-type impurities. In an embodiment, the capping pattern 163B may include n-type doped silicon which includes n-type impurities as a majority carrier.

The memory layer 161A or 161 may cover a sidewall of the channel pillar CHP. The memory layer 161A or 161 may include a tunnel insulating layer, a data storage layer, and a blocking insulating layer. Although not shown in the drawings, the tunnel insulating layer is interposed between the channel pillar CHP and the gate stack structure 160, the data storage layer is interposed between the tunnel insulating layer and the gate stack structure 160, and the blocking insulating layer is interposed between the data storage layer and the gate stack structure 160. The tunnel insulating layer may include an oxide, such as silicon dioxide (SiO₂). The data storage layer may include a material layer capable of storing data that is changed using Fowler Nordeheim tunneling. In an embodiment, the data storage layer may include a charge trap insulating layer or an insulating layer including conductive nanodots. The charge trap insulating layer may include a silicon nitride layer. The blocking insulating layer may include an oxide, such as silicon dioxide (SiO₂), a high-dielectric insulator having a higher dielectric constant than silicon dioxide, or the like. The high-dielectric insulating material may include an aluminum oxide layer, a hafnium oxide layer, or the like.

The source select transistor may be formed at an intersection of the source select line SSL and the channel layer 163A, the drain select transistor may be formed at an intersection of the drain select line DSL and the channel layer 163A, and the plurality of memory cells may be formed at intersections of the plurality of word lines WL and the channel layer 163A. The source select transistor, the plurality of memory cells, and the drain select transistor may be connected in series through the channel layer 163A of the channel pillar CHP to form the memory cell string MS illustrated in FIG. 8.

The channel pillar CHP may be connected to the doped semiconductor structure 150 or 180 and the bit line BL.

The doped semiconductor structure 150 or 180 may include at least one doped semiconductor layer. The doped semiconductor layer of the doped semiconductor structure 150 or 180 may include n-type impurities or p-type impurities. In an embodiment, the doped semiconductor structure 150 or 180 may include at least one of a first conductive doped semiconductor layer including n-type impurities as a majority carrier and a second conductive doped semiconductor layer including p-type impurities as a majority carrier. The first conductive doped semiconductor layer may be provided as a source layer, and the second conductive doped semiconductor layer may be provided as a well region. The source layer of the doped semiconductor structure 150 or 180 may be in direct contact with the sidewall or a bottom surface of the channel pillar CHP.

Referring to FIG. 9A, in an embodiment, a portion of a sidewall of the channel layer 163A may form a contact surface with the doped semiconductor structure 150. In an embodiment, the doped semiconductor structure 150 may include a first source layer 151, a second source layer 155, and a contact source layer 153 between the first source layer 151 and the second source layer 155. Each of the first source layer 151, the second source layer 155, and the contact source layer 153 may include a doped semiconductor layer. The channel layer 163A may extend through the second source layer 155, through the contact source layer 153, and into the first source layer 151. The memory layer 161A may extend between the second source layer 155 and the channel layer 163A. A dummy memory layer 161B may be disposed between the first source layer 151 and the channel layer 163A. The dummy memory layer 161B may include the same materials as the memory layer 161A. The contact source layer 153 may be interposed between the memory layer 161A and the dummy memory layer 161B, and it may be in contact with the channel layer 163A.

Referring to FIG. 9B, an end of the channel layer 163A may extend into the doped semiconductor structure 180 and may form a contact surface with the doped semiconductor structure 180.

Referring to FIGS. 9A and 9B, the capping pattern 163B of the channel pillar CHP may be electrically connected to the bit line BL via a bit line connection structure 173. The bit line connection structure 173 may be disposed in an insulating structure 171. The insulating structure 171 may include multiple insulating layers covering the gate stack structure 160. The bit line connection structure 173 may have one or more conductive patterns. In an embodiment, the bit line connection structure 173 may be formed in an integrated conductive pattern including a contact portion and a pad portion. In another embodiment, the bit line connection structure 173 may include a first conductive pattern 173A and a second conductive pattern 173B that vertically overlap with each other.

The bit line BL may be disposed in the insulating structure 171.

The doped semiconductor structure 150 or the bit line BL may be adjacent to the peripheral circuit insulating structure 101. In an embodiment, as shown in FIG. 9A, the doped semiconductor structure 150 may be closer to the peripheral circuit insulating structure 101 than the bit line BL. In another embodiment, as shown in FIG. 9B, the bit line BL may be closer to the peripheral circuit insulating structure 101 than the doped semiconductor structure 180.

Referring to FIG. 9A, in an embodiment, a cell array structure, such as the doped semiconductor structure 150, may be formed over the peripheral circuit insulating structure 101.

Referring to FIG. 9B, in an embodiment, the gate stack structure 160 and the like may be formed separately from the peripheral circuit structure and connected to the peripheral circuit structure by a bonding process. In this case, the peripheral circuit structure may further include a peripheral circuit-side intervening insulating layer 141, a peripheral circuit-side bonding pad PBP, and a peripheral circuit-side bonding contact PBC over the peripheral circuit insulating structure 101. The peripheral circuit-side bonding pad PBP may be disposed in the peripheral circuit-side intervening insulating layer 141. The peripheral circuit-side bonding contact PBC extends from the peripheral circuit-side bonding pad PBP to connect to the uppermost conductive pattern 136 of the interconnection 130. In addition, the semiconductor memory device may further include a cell-side intervening insulating layer 175 covering the insulating structure 171, a cell-side bonding pad CBP and a cell-side bonding contact CBC in the cell-side intervening insulating layer 175. The cell-side bonding contact CBC may extend from the cell-side bonding pad CBP to connect to the cell array structure. In an embodiment, the cell-side bonding contact CBC may extend from the cell-side bond pad CBP to connect to the bit line BL.

Prior to the bonding process, the gate stack structure 160, the memory layer 161, the channel pillar CHP, the bit line connection structure 173, the insulating structure 171, the bit line BL, the cell-side intervening insulating layer 175, the cell-side bonding contact CBC, and the cell-side bonding pad CBP may be formed over a sacrificial substrate. Subsequently, the cell-side bonding pad CBP is bonded to the peripheral circuit-side bonding pad PBP, and after removing the sacrificial substrate, the end of the channel layer 163A facing a direction opposite to the direction toward the bit line BL may be exposed. The doped semiconductor structure 180 may be formed to expose the end of the channel layer 163A and then contact the exposed end of the channel layer 163A.

According to some embodiments of the present disclosure, an auxiliary conductive line is disposed between conductive lines involved in operation of a semiconductor memory device to provide a wiring array structure, and a voltage applied to the auxiliary conductive line is controlled to improve the breakdown voltage characteristic of the wiring array structure.

According to some embodiments of the present disclosure, when a first voltage and a second voltage used for operation of a semiconductor memory device are applied to a wiring array structure including a first conductive line, a second conductive line, and an auxiliary conductive line between the first conductive line and the second conductive line, a voltage having a level between the first voltage and the second voltage is applied to the auxiliary conductive line. As a result, voltage differences between adjacent conductive lines of the wiring array structure may be reduced. Accordingly, the breakdown voltage characteristics of the wiring array structure may be improved, thereby improving the operational reliability of the semiconductor memory device.

What is claimed is:

1. A semiconductor memory device, comprising:
a wiring array structure including a first conductive line, a second conductive line, and an auxiliary conductive line extending in parallel to each other, wherein the auxiliary conductive line is disposed between the first conductive line and the second conductive line; and
a peripheral circuit structure including a voltage generator, the peripheral circuit structure configured to supply voltages to the first conductive line, the second conductive line, and the auxiliary conductive line,
wherein, when a first voltage is applied to the first conductive line and a second voltage lower than the first voltage is applied to the second conductive line, the voltage generator applies a third voltage having a level between the first voltage and the second voltage to the auxiliary conductive line.

2. The semiconductor memory device of claim 1, wherein the third voltage is the average of the first voltage and the second voltage.

3. The semiconductor memory device of claim 1, wherein the voltage generator includes a charge pump configured to output a pump generating a voltage between 10 V and 30 V and a ground voltage.

4. The semiconductor memory device of claim 3, wherein the first conductive line is connected to a first terminal outputting the pump generating voltage, and
wherein the second conductive line is connected to a second terminal outputting the ground voltage.

5. The semiconductor memory device of claim 1, further comprising a cell array structure including a plurality of memory cells configured to be controlled in operation by the peripheral circuit structure,
wherein the wiring array structure is disposed between the peripheral circuit structure and the cell array structure.

6. A semiconductor memory device, comprising:
a wiring array structure including a first conductive line, a second conductive line, and at least two auxiliary conductive lines extending in parallel to each other, wherein the at least two auxiliary conductive lines are disposed between the first conductive line and the second conductive line; and
a peripheral circuit structure including a voltage generator, the peripheral circuit structure configured to supply voltages to the first conductive line, the second conductive line, and the at least two auxiliary conductive lines,
wherein, when a first voltage is applied to the first conductive line and a second voltage lower than the first voltage is applied to the second conductive line, the voltage generator applies auxiliary voltages set to different levels between the first voltage and the second voltage to the at least two auxiliary conductive lines.

7. The semiconductor memory device of claim 6, wherein, when the first voltage is applied to the first conductive line and the second voltage is applied to the second conductive line, the voltage generator is configured to stepwise reduce the auxiliary voltages applied to the at least two auxiliary lines from the voltage of the first conductive line to the voltage of the second conductive line.

8. The semiconductor memory device of claim 6, wherein, when the first voltage is applied to the first conductive line and the second voltage is applied to a second conductive line, the voltage generator generates the auxiliary voltages such that voltage differences between adjacent conductive lines of the wiring array structure are the same.

9. The semiconductor memory device of claim 6, wherein the at least two auxiliary lines include a first auxiliary conductive line adjacent to the first conductive line and a second auxiliary conductive line adjacent the second conductive line,
wherein the auxiliary voltages include a first auxiliary voltage applied to the first auxiliary conductive line and a second auxiliary voltage applied to the second auxiliary conductive line,
wherein the first auxiliary voltage is a voltage at a level obtained by subtracting a third (⅓) of the difference between the first voltage and the second voltage from the first voltage, and
wherein the second auxiliary voltage is a voltage at a level obtained by subtracting two thirds (⅔) of the difference between the first voltage and the second voltage from the first voltage.

10. The semiconductor memory device of claim 6, wherein the voltage generator includes a charge pump configured to output a pump generating voltage between 10 V and 30 V and a ground voltage.

11. The semiconductor memory device of claim 10, wherein the first conductive line is connected to a first terminal outputting the pump generating voltage, and
wherein the second conductive line is connected to a second terminal outputting the ground voltage.

12. The semiconductor memory device of claim 6, further comprising a cell array structure including a plurality of memory cells configured to be controlled in operation by the peripheral circuit structure,
wherein the wiring array structure is disposed between the peripheral circuit structure and the cell array structure.
